(19) United States
(12) Patent Application Publication
(10) Pub. No.: US 2011/0065053 A1
(43) Pub. Date: Mar. 17, 2011

(54) MATERIAL FOR FORMING PROTECTIVE FILM AND METHOD FOR FORMING PHOTORESIST PATTERN

(75) Inventors: Masaaki YOSHIDA, Kawasaki-shi (JP); Kiyoshi ISHIKAWA, Kawasaki-shi (JP); Atsushi SAWANO, Kawasaki-shi (JP); Yuriko SHIRAI, Kawasaki-shi (JP); Takumi NAMIKI, Kawasaki-shi (JP)

(73) Assignee: TOKYO OHKA KOGYO CO., LTD., Kawasaki-shi (JP)

(21) Appl. No.: 12/879,809

(22) Filed: Sep. 10, 2010

(30) Foreign Application Priority Data
Sep. 15, 2009 (JP) 2009-213791

(51) Int. Cl. G03F 7/20; C08F 32/08; C08L 55/00

(52) U.S. Cl. 430/325; 526/281; 524/553

(57) ABSTRACT

The present invention provides a material for forming a protective film that has favorable alkali solubility and gives a protective film excelling in water repellency, as well as a method for forming a photoresist pattern using this material for forming a protective film. The material for forming a protective film of the present invention contains an alkali-soluble polymer having a unit derived from a monomer represented by the following general formula (A-1) as a constitutional unit.

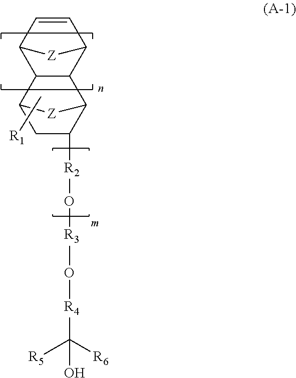

In the general formula (A-1), R₁ is a hydrogen atom, an alkyl group having 1 to 6 carbon atoms, or the like; R₂, R₃, and R₄ are each independently an alkylene chain having 1 to 6 carbon atoms or the like; R₅ and R₆ are each independently an alkyl group or fluoroalkyl group having 1 to 15 carbon atoms or the like; and at least one of R₅ and R₆ is a fluoroalkyl group; Z is an alkylene chain having 1 to 2 carbon atoms or an oxygen atom; m is 0 or 1; and n is an integer of 0 to 3.

This application is based on and claims the benefit of priority from Japanese Patent Application No. 2009-213791, filed on 15 Sep. 2009, the content of which is incorporated herein by reference.

### BACKGROUND OF THE INVENTION

1. Field of the Invention

The present invention relates to a material for forming a protective film that is laminated on a photoresist film, and a method for forming a photoresist pattern using this material for forming a protective film.

2. Related Art

In recent years, a liquid immersion exposure process has been reported as a new lithographic technique (see Non-patent Documents 1 to 3). According to this liquid immersion exposure process, a conventional exposure light path space is replaced with a so-called liquid for liquid immersion exposure (e.g., pure water, a fluorine based inert liquid, or the like), whereby a photoresist pattern having a higher resolution and an excellent focal depth can be formed even if using a light source of the same exposure wavelength (refer to Patent Documents 1 and 2).

In addition, in recent years, a technique in which removal of the protective film and formation of the photoresist pattern are simultaneously performed during alkali development after the liquid immersion exposure using an alkali-soluble protective film has been proposed from the viewpoint of simplifying the photoresist pattern formation process and improving production efficiency (refer to Patent Document 2).

### PRIOR ART DOCUMENTS

### Patent Documents

Patent Document 1: PCT International Publication No. WO 2004/068242

Patent Document 2: Japanese Unexamined Patent Application, Publication No. 2008-076638

### Non-Patent Documents

Non-Patent Document 1: Journal of Vacuum Science & Technology B (Published in U.S.A.), vol. 17, No. 6, pp. 3306-3309, 1999.

Non-Patent Document 2: Journal of Vacuum Science & Technology B (Published in U.S.A.), vol. 19, No. 6, pp. 2353-2356, 2001.

Non-Patent Document 3: Proceedings of SPIE (Published in U.S.A.), Vol. 4691, pp. 459-465, 2002.

### SUMMARY OF THE INVENTION

Herein, the material for forming a protective film disclosed in Patent Document 2 is characterized by containing an alkali-soluble polymer and an ether-type solvent. With the material for forming a protective film disclosed in Patent Document 2, although it has been possible to reduce the damage to the photoresist pattern and to form a photoresist pattern of a favorable rectangular shape due to using an ether-type solvent, there has been room for further improvement in the water repellency of the protective film thus obtained.

Herein, the water repellency of the protective film influences the ability of the liquid for liquid immersion exposure to follow the lens (lens followability) during liquid immersion exposure of a scan type, and thus is strongly related to productivity. In particular, in recent years, the scanning speed during exposure has become high speed with the object of improving productivity; therefore, a further improvement in the lens following of the liquid for liquid immersion exposure has been desired.

In addition, the alkali solubility of the protective film is also important from the point of productivity. As a result, a material for forming a protective film having favorable alkali solubility and giving a protective film excelling in water repellency has been demanded.

The present invention was made taking into account the above-mentioned problems, and has an object of providing a material for forming a protective film that has favorable alkali solubility and gives a protective film excelling in water repellency, as well as a method for forming a photoresist pattern using this material for forming a protective film.

As a result of thorough research to achieve the above-mentioned object, the present inventors have found that the above-mentioned problem could be solved by including in the material for forming a protective film an alkali-soluble polymer having a unit derived from a specific monomer having a side chain containing an ether bond, thereby arriving at completion of the present invention. More specifically, the present invention provides the following.

According to a first aspect of the present invention, a material for forming a protective film that forms a protective film to be laminated on a photoresist film includes an alkali-soluble polymer having a unit derived from a monomer represented by the following general formula (A-1) as a constitutional unit.

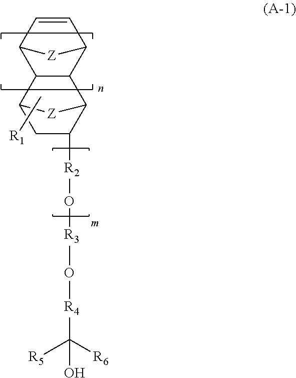

In the general formula (A-1), R₁ is a hydrogen atom or a straight chain, branched chain or cyclic alkyl group or fluoroalkyl group having 1 to 6 carbon atoms; R₂, R₃, and R₄ are each independently an alkylene chain or fluoroalkylene chain having 1 to 6 carbon atoms; R₅ and R₆ are each independently a straight chain, branched chain or cyclic alkyl group or fluoroalkyl group having 1 to 15 carbon atoms, where a portion of the alkyl group may be bound via an ether linkage, and a portion of the hydrogen atoms of the alkyl group, or the hydrogen atoms or fluorine atoms of the fluoroalkyl group may be each substituted by a hydroxyl group; and at least one among R₅ and R₆ is a fluoroalkyl group; Z is an alkylene chain having 1 to 2 carbon atoms or an oxygen atom; m is 0 or 1; and n is an integer of 0 to 3.

It should be noted that the “constitutional unit” in the present specification and the scope of the present patent claims means a monomer unit (single unit) constituting a polymer compound (polymer, copolymer).

According to a second aspect of the present invention, a method for forming a photoresist pattern includes the steps of: providing a photoresist film on a substrate; forming a protective film on the photoresist film using the material for forming the protective film of the present invention; selectively exposing the photoresist film through the protective film; and removing the protective film by way of a developing solution, and developing the photoresist film after exposure.

According to a third aspect of the present invention, a method for forming a photoresist pattern using a liquid immersion exposure process includes the steps of: providing a photoresist film on a substrate; forming a protective film on the photoresist film using the material for forming the protective film of the present invention; disposing a liquid for liquid immersion exposure at least on the protective film on the substrate, and selectively exposing the photoresist film through the liquid for liquid immersion exposure and the protective film; and removing the protective film by way of a developing solution, and developing the photoresist film after exposure.

According to the present invention, it is possible to provide a material for forming a protective film that has favorable alkali solubility and gives a protective film excelling in water repellency, as well as a method for forming a photoresist pattern using this material for forming a protective film.

### DETAILED DESCRIPTION OF THE INVENTION

### Material for Forming Protective Film

The material for forming a protective film of the present invention contains an alkali-soluble polymer having units derived from a monomer represented by the general formula (A-1) as a constitutional unit. Each component contained in the material for forming a protective film of the present invention will be explained hereinafter.

### (a) Alkali-Soluble Polymer

In the present invention, a polymer at least having a unit derived from a monomer represented by the general formula (A-1) as a constitutional unit is used as the alkali-soluble polymer (a).

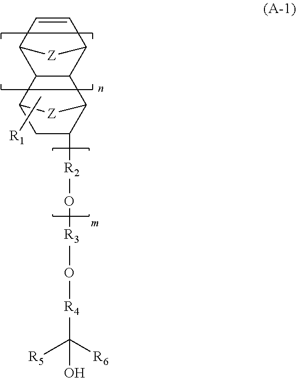

In the above general formula (A-1), R₁ is a hydrogen atom, or straight chain, branched chain, or cyclic alkyl group or fluoroalkyl group having 1 to 6 carbon atoms, R₂, R₃, and R₄ are each independently an alkylene chain or fluoroalkylene chain having 1 to 6 carbon atoms, R₅ and R₆ are each independently a straight chain, branched chain, or cyclic alkyl group or fluoroalkyl group (where a portion of the alkyl group may be bound via an ether linkage, and further, a portion of the hydrogen atoms of the alkyl group, or the hydrogen atoms or fluorine atoms of the fluoroalkyl group may be substituted by a hydroxyl group), and at least one of R₅ and R₆ is a fluoroalkyl group, Z is an alkylene chain having 1 to 2 carbon atoms or an oxygen atom, m is 0 or 1, and n is an integer of 0 to 3.

In particular, other than a hydrogen atom, a straight chain alkyl group such as a methyl group, ethyl group, n-propyl group, n-butyl group, n-pentyl group, and n-hexyl group, a branched chain alkyl group such as an isopropyl group, 1-methylpropyl group, 2-methylpropyl group, and tert-butyl group, a cyclic alkyl group such as a cyclopentyl group and cyclohexyl group, and the like are specifically exemplified as R₁. A portion or all of the hydrogen atoms of these alkyl groups may be substituted by a fluorine atom. Above all, from the point of improving water repellency, being a perfluoroalkyl group in which all of the hydrogen atoms of these alkyl groups have been substituted by fluorine atoms is preferred, and being a trifluoromethyl group is particularly preferred.

In addition, a straight alkylene chain such as a methylene chain, ethylene chain, n-propylene chain, n-butylene chain, n-pentylene chain, and n-hexylene chain, a branched alkylene chain such as a 1-methylpropylene chain and 2-methylpropylene chain, and the like are specifically exemplified as R₂, R₃, and R₄. A portion or all of the hydrogen atoms of these alkylene chains may be substituted by fluorine atoms.

In addition, a straight chain alkyl group such a methyl group, ethyl group, n-propyl group, n-butyl group, n-pentyl group, n-decyl group, and n-pentadecyl group, a branched chain alkyl group such as an isopropyl group, 1-methylpropyl group, 2-methylpropyl group, and tert-butyl group, a cyclic alkyl group such as a cyclopentyl group and cyclohexyl group, and the like are specifically exemplified as R₅ and R₆. It should be noted that at least one of R₅ and R₆ is a fluoroalkyl group in which a portion or all of the hydrogen atoms of these alkyl groups has been substituted by fluorine atoms, and R₅ and R₆ are both preferably fluoroalkyl groups. In addition, a portion of the alkyl group may be bound via an ether linkage, and further, a portion of the hydrogen atoms of the alkyl group, or the hydrogen atoms or fluorine atoms of the fluoroalkyl group may be substituted by a hydroxyl group.

Furthermore, in the above general formula (A-1), Z is preferably a methylene chain. In addition, m is preferably 1, and n is preferably 0.

The alkali solubility of the protective film obtained is satisfactorily maintained, and the water repellency can be improved by incorporating the unit derived from the monomer represented by the general formula (A-1) into the alkali-soluble polymer (a) used in the material for forming a protective film.

The alkali-soluble polymer (a) preferably contains at least 50 mol % of units derived from the monomer represented by the general formula (A-1) among all constitutional units, more preferably contains at least 80 mol %, and most preferably only has units derived from monomers represented by the above general formula (A-1) as constitutional units.

If the alkali-soluble polymer (a) contains units derived from monomers represented by the general formula (A-1), it may be a homopolymer obtained from a single monomer, or may be a copolymer obtained from a plurality of types of monomers.

In a case of the alkali-soluble polymer (a) being a copolymer with a monomer other than monomers represented by the general formula (A-1), at least one type of monomer selected from among the monomers represented by the following general formulae (A-2), (A-3), (A-4), and (A-5) are exemplified as suitable monomers to be copolymerized with the monomer represented by the general formula (A-1).

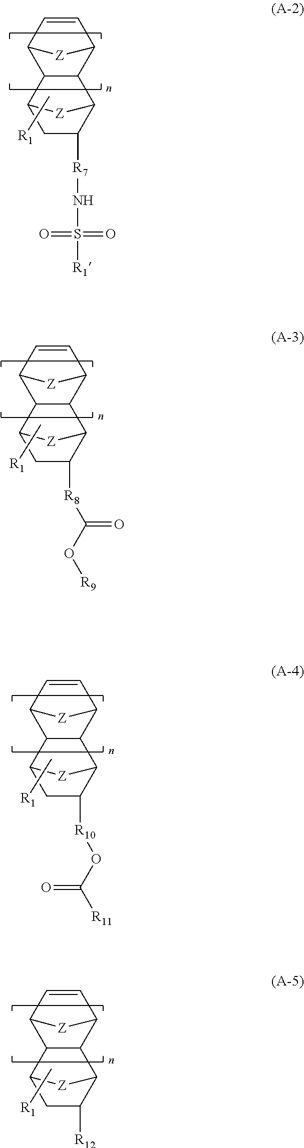

In the above general formulae (A-2), (A-3), (A-4), and (A-5), R₇, R₈, and R₁₀ are each independently a single bond or an alkylene chain or fluoroalkylene chain having 1 to 6 carbon atoms, R₁′ is a hydrogen atom, or straight chain, branched chain, or cyclic alkyl group or fluoroalkyl group having 1 to 6 carbon atoms, R₉, R₁₁, and R₁₈ are each independently a straight chain, branched chain, or cyclic alkyl group or fluoroalkyl group having 1 to 15 carbon atoms (where a portion of the alkyl groups may be bound via an ether linkage, and further, a portion of the hydrogen atoms of the alkyl group, or the hydrogen atoms or fluorine atoms of the fluoroalkyl group may be substituted by a hydroxyl group), and R₁, Z, and n have the same definition as in the above general formula (A-1).

The monomers represented by the above general formulae (A-2), (A-3), (A-4), and (A-5) are preferably monomers represented by the following general formulae (A-6), (A-7), (A-8), and (A-9), respectively.

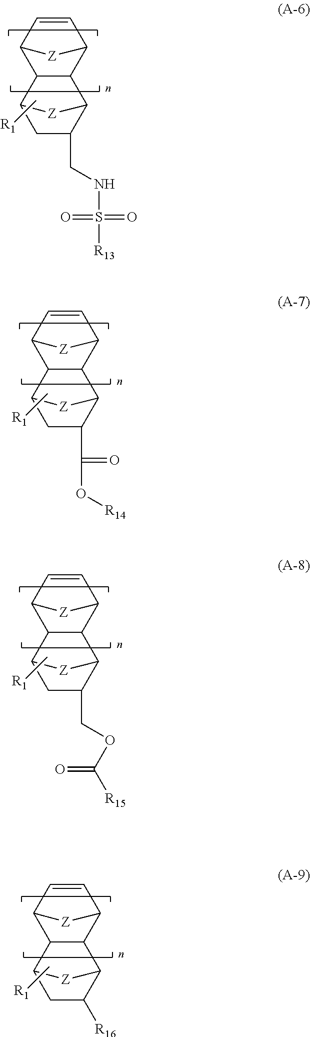

In the above general formulae (A-6), (A-7), (A-8), and (A-9), R₁₃ is a straight chain, branched chain or cyclic alkyl group or fluoroalkyl group having 1 to 6 carbon atoms; R₁₄ is a straight chain or branched chain alkyl group or fluoroalkyl group having 2 to 10 carbon atoms (where a portion of the hydrogen atoms of the alkyl group, or the hydrogen atoms or fluorine atoms of the fluoroalkyl group may be substituted by a hydroxyl group); R₁₅ is a straight chain or branched chain alkyl group or fluoroalkyl group having 5 to 10 carbon atoms (where a portion of the hydrogen atoms of the alkyl group, or the hydrogen atoms or fluorine atoms of the fluoroalkyl group may be substituted by a hydroxyl group); R₁₆ is a straight chain or branched chain alkyl group or fluoroalkyl group having 1 to 10 carbon atoms (where a portion of the hydrogen atoms of the alkyl group, or the hydrogen atoms or fluorine atoms of the fluoroalkyl group may be substituted by a hydroxyl group); and R₁, Z, and n have the same definition as in the above-mentioned general formula (A-1).

Above all, R₁₃ is preferably a substituent selected from among —CF₃ and —C₂F₅; R₁₄ is preferably a substituent selected from among —CH₂C₂F₅, —C(CH₃) CH₂C(CF₃)₂OH, —CH₂C₃F₇, and —CH₂C₄F₉; R₁₅ is preferably a substituent selected from among —C₇F₁₅, —CF₂CF (CF₃) CF₂CF₂CF₂CF (CF₃)₂, and —CF₂CF(CF₃)CF₂C(CF₃)₃, and R₁₆ is preferably a substituent selected from among —CH₂C₂F₅, —C(CH₃) CH₂C(CF₃)₂OH, —CH₂C₃F7, and —CH₂C₄F₉.

It is possible to adjust the alkali solubility and water repellency by incorporating a unit derived from at least one selected from among monomers represented by the above general formulae (A-2), (A-3), (A-4), and (A-5) in the alkali-soluble polymer (a).

In a case of the alkali-soluble polymer (a) being a copolymer obtained by copolymerizing a monomer represented by the above general formula (A-1) with at least one type selected from among the monomers represented by the above formulae (A-2), (A-3), (A-4), and (A-5), the constituent ratio (mole ratio) of the monomer represented by the above general formula (A-1) to the at least one selected from among the monomers represented by the above general formulae (A-2), (A-3), (A-4), and (A-5) is preferably 50:50 to 95:5, more preferably 60:40 to 90:10, and even more preferably 70:30 to 85:15.

The alkali-soluble polymer (a) explained above may be used as a single polymer, and may be used by mixing with a plurality of polymers. In addition, one or a plurality of arbitrary alkali-soluble polymers not containing a unit derived from a monomer unit represented by the general formula (A-1) may be used by mixing with the alkali soluble polymer (a) in a range that does not inhibit the object of the present invention.

Such an alkali-soluble polymer (a) can be synthesized by publicly known methods. In addition, the mass average molecular weight (Mw) of this polymer in terms of polystyrene by GPC (gel-permeation chromatography) is not particularly limited, but is preferably 2,000 to 80,000, more preferably 3,000 to 50,000, and even more preferably 3,000 to 30,000.

The amount of the alkali-soluble polymer (a) to be blended is preferably about 0.1 to 20% by mass and more preferably 0.3 to 10% by mass based relative to the total amount of the material for forming the protective film.

### (b) Solvent

In the material for forming the protective film of the present invention, for example, an alkyl alcohol (b-1), a fluoroalkyl alcohol in which a portion or all of the hydrogen atoms have been substituted by fluorine atoms (b-2), an ether (b-3), a fluoroalkyl ether and fluoroalkyl ester in which a portion or all of the hydrogen atoms have been substituted by fluorine atoms (b-4), and the like are exemplified as the solvent for dissolving the alkali-soluble polymer (a).

The above-mentioned alkyl alcohol (b-1) preferably has 1 to 10 carbon atoms. More specifically, at least one selected from among ethanol, propanol, n-butanol, isobutanol, n-pentanol, 4-methyl-2-pentanol, and 2-octanol can be used. Among these, at least one selected from among isobutanol and 4-methyl-2-pentanol is preferably used.

The above-mentioned fluoroalkyl alcohol in which a portion or all of the hydrogen atoms have been substituted by fluorine atoms (b-2) preferably has 4 to 12 carbon atoms. More specifically, at least one selected from among C₄F₉CH₂CH₂OH and C3F7CH₂OH can be used.

An alkyl ether, a terpene-based solvent having an ether linkage, or the like can be used as the above-mentioned ether (b-3). The alkyl ether preferably has 2 to 10 carbon atoms, and more preferably has 3 to 8 carbon atoms. As such an alkyl ether, more specifically, at least one selected from among dimethyl ether, diethyl ether, methyl ethyl ether, dipropyl ether, diisopropyl ether, dibutyl ether, diamyl ether, and diisoamyl ether can be used. Among these, at least one selected from among diisopropyl ether, dibutyl ether, diamyl ether, and diisoamyl ether is preferably used. As the terpene-based solvent having an ether linkage, more specifically, 1,4-cineol, 1,8-cineol, pinene oxide, and the like are exemplified. Above all, 1,4-cineol and 1,8-cineol are preferable due to ease of industrial accessibility, etc.

The above-mentioned fluoroalkyl ether and fluoroalkyl ester in which a portion or all of the hydrogen atoms have been substituted by fluorine atoms (b-4) used preferably has 3 to 15 carbon atoms.

As the above-mentioned fluoroalkyl ether, at least one selected from among fluoroalkyl ethers represented by R_{A}OR_{B} (R_{A} and R_{B} are each independently an alkyl group, the total number of carbon atoms of both alkyl groups is 3 to 15, in which at least a portion or all of the hydrogen atoms thereof are substituted by fluorine atoms) can be used.

As the above-mentioned fluoroalkyl ester, at least one selected from among fluoroalkyl esters represented by R_{A}COOR_{B} (R_{A} and R_{B} are each independently an alkyl group, the total number of carbon atoms of both alkyl groups is 3 to 15, in which at least a portion or all of the hydrogen atoms thereof are substituted by fluorine atoms) can be used.

Compounds represented by the following structural formula (B-1) are exemplified as suitable examples of the above-mentioned fluoroalkyl ether. In addition, a compound represented by the following structural formulae (B-2) and (B-3) or the like are exemplified as ideal examples of the above-mentioned fluoroalkyl ester. However, the fluoroalkyl ether and the fluoroalkyl ester are not limited to these.

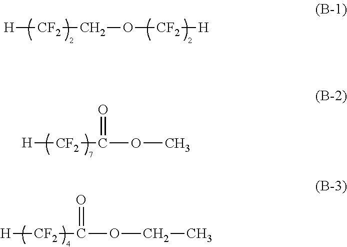

These solvents can be used independently or by combining at least two thereof as necessary. Furthermore, it is also possible to use by combining with a paraffin-based solvent such as n-heptane, or a fluorine-based solvent such as fluoro-2-butyl tetrahydrofuran in a range that does not hinder the effects of the present invention.

### (c) Cross-Linking Agent

The material for forming the protective film of the present invention may further contain a cross-linking agent (c) as necessary. At least one nitrogen-containing compound selected from among a nitrogen-containing compound having an amino group in which a hydrogen atom has been substituted by at least one substituent selected from among a hydroxyalkyl group and an alkoxyalkyl group, and a nitrogen-containing compound having an imino group in which a hydrogen atom has been substituted by at least one substituent selected from among a hydroxyalkyl group and an alkoxyalkyl group can be used as the (c) cross-linking agent.

A melamine derivative, urea derivative, guanamine derivative, acetoguanamine derivative, benzoguanamine derivative, or succinylamide derivative in which hydrogen atoms of the amino group have been substituted by a methylol group and/or an alkoxymethyl derivative; a glycoluril derivative or ethylene urea derivative in which a hydrogen atom of the imino group has been substituted; and the like are exemplified as these nitrogen-containing compounds.

These nitrogen-containing compounds are obtained by methylolating by causing the aforementioned nitrogen-containing compounds to react with formalin in boiling water, or by alkoxylating by causing a lower alcohol, more specifically, methanol, ethanol, n-propanol, isopropanol, n-butanol, isobutanol or the like, to further react in this. Above all, a suitable cross-linking agent is tetrabutoxy methylated gylcoluril.

Furthermore, a condensation reaction product of a hydrocarbon compound substituted by at least one substituent selected from among a hydroxyl group and alkoxy group, and a monohydroxy-monocarboxylic acid compound can be suitably used as the cross-linking agent (c). As the above-mentioned monohydroxy-monocarboxylic acid, a compound in which the hydroxyl group and carboxyl group are bonded at the same carbon atom or two adjacent carbon atoms is preferable.

In a case of blending the cross-linking agent (c), the blending amount thereof is preferably set to about 0.5 to 10% by mass with respect to the blending amount of the alkali-soluble polymer (a).

### (d) Acidic Compound

The material for forming a protective film of the present invention may further blend an acidic compound (d) as necessary. By adding this acidic compound (d), a shape-refining effect on the photoresist pattern is obtained, and after liquid immersion exposure has been performed, it is possible to effectively suppress negative effects due to amines by interposing the protective film, even in a case of the photoresist film being exposed in an atmosphere containing a small amount of amine prior to developing (post exposure delay). With this, it is possible to prevent great deviation in the dimensions of the photoresist pattern obtained by development thereafter from occurring.

As such an acidic compound (d), for example, at least one selected from among the following general formulae (D-1), (D-2), (D-3), and (D-4) are exemplified.

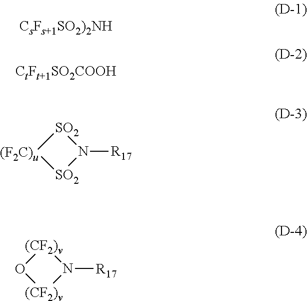

In the above general formulae (D-1), (D-2), (D-3), and (D-4), s is an integer of 1 to 5; t is an integer of 10 to 15; u is 2 or 3; v is each independently 2 or 3; and R₁₇ is each independently an alkyl group or fluoroalkyl group having 1 to 15 carbon atoms (a portion of the hydrogen atoms or fluorine atoms may be substituted by a hydroxyl group, alkoxy group, carboxyl group, or amino group).

Such an acidic compound is not the target of any Significant New Use Rule (SNUR), and reportedly does not have a negative effect on the human body.

As the acidic compound represented by the above general formula (D-1), (C₄F₉SO₂)₂NH, (C₃F₇SO₂)₂NH, etc. are specifically preferred, and as the acidic compound represent by the above general formula (D-2), C₁₀F₂₁COOH, etc. are specifically preferred.

In addition, as the acidic compounds represented by the above general formulae (D-3) and (D-4), compounds represent by the following formulae (D-5) and (D-6), respectively, are specifically preferable.

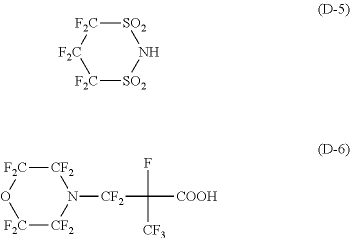

In a case of blending an acidic compound (d), the blending amount thereof is preferably about 0.1 to 10% by mass relative to the overall amount of the material for forming the protective film, and more preferably about 0.1 to 3.0% by mass.

(e) Acid-Generating Additive that Generates Acid in Presence of Acid

The material for forming a protective film of the present invention may further blend an acid-generating additive (e) as necessary. This acid-generating additive (e) does not have a function of generating acid independently, but causes acid to be generated by coming to exist with an acid. With this, even in a case of the acid generated by an acid generator in the photoresist film having diffused in the protective film, the acid generated by the acid-generating additive in the protective film by this acid compensates for insufficient acid in the photoresist film, and is able to suppress deterioration of the resolution of the photoresist pattern and a decline in the focal depth width, whereby finer photoresist pattern formation becomes possible.

Such an acid-generating additive (e) is preferably an alicyclic hydrocarbon compound having both a carbonyl group and a sulfonyl group in the molecule.

More specifically, such an acid-generating additive (e) is preferably at least one selected from among the compounds represented by the following general formulae (E-1) and (E-2).

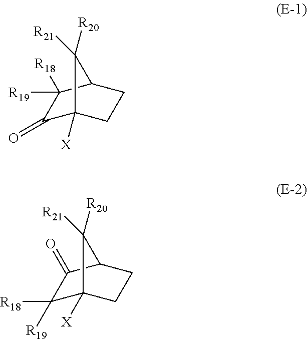

In the above general formulae (E-1) and (E-2), R₁₈, R₁₉, R₂₀, and R₂₁ are each independently a hydrogen atom, or a straight chain or branched chain alkyl group having 1 to 10 carbon atoms, and X is an electrophilic group having a sulfonyl group.

Herein, a straight chain or branched chain saturated hydrocarbon group such as a methyl group, ethyl group, propyl group, isopropyl group, n-butyl group, isobutyl group, sec-butyl group, tert-butyl group, amyl group, isoamyl group, tert-amyl group, hexyl group, heptyl group, octyl group, isooctyl group, 2-ethylhexyl group, tert-octyl group, nonyl group, isononyl group, decyl group, isodecyl group, and the like are exemplified as the “straight chain or branched chain alkyl group having 1 to 10 carbon atoms”.

In addition, X is an “electrophilic group having a sulfonyl group”. Herein, the “electrophilic group having a sulfonyl group” preferably is —O—SO₂—Y. Y is an alkyl group having 1 to 5 carbon atoms or an alkyl halide group having 1 to 10 carbon atoms. Above all, Y preferably is a fluoroalkyl group.

More specifically, compounds represented by the above formulae (E-3) to (E-10) are exemplified as compounds represent by the following general formulae (E-1) and (E-2).

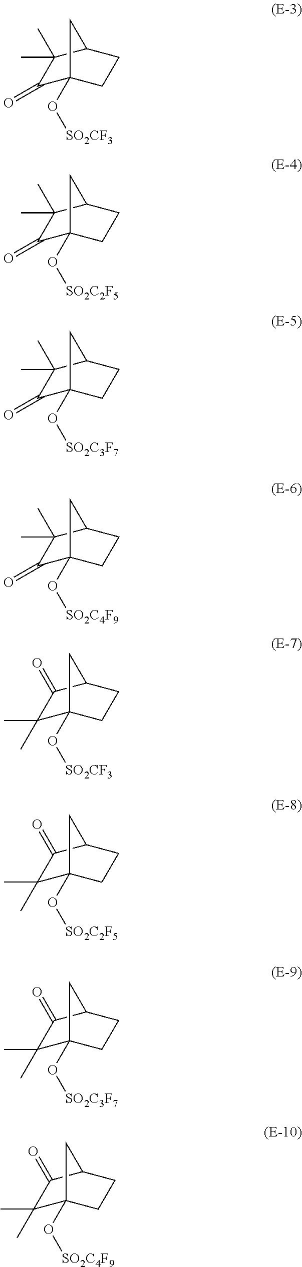

In a case of blending the acid-generating additive (e), the blending amount thereof is preferably set to 0.1 to 50 parts by mass relative to 100 parts by mass of the alkali-soluble polymer, and more preferably set to 1 to 20 parts by mass. By setting to such a range, acid is effectively generated relative to the acid eluted from the photoresist film, without generating coating unevenness, and thus it is possible to improve the photoresist pattern shape.

### (f) Other

The material for forming a protective film of the present invention may further blend a surfactant (f). Although “XR-104” (trade name: Dainippon Ink and Chemicals, Incorporated) is exemplified as this surfactant, it is not limited thereto. By blending such a surfactant, film properties and the controllability of effluent can be greatly improved.

In a case of blending a surfactant, the blending amount thereof is preferably from 0.001 parts by mass to 10 parts by mass relative to 100 parts by mass of the alkali-soluble polymer (a).

### Contact Angle of Protective Film to Water

The water repellency of the protective film obtained using the material for forming a protective film of the present invention can be evaluated by measuring the contact angle relative to water, e.g., the static contact angle (the angle made by the water drop surface on the photoresist film and the photoresist film surface in a horizontal state), the dynamic contact angle (the contact angle when the water drop begins to slide when the photoresist film is made to slope; there is a contact angle at an end point at the front in the falling direction (advancing angle) and a contact angle at an end point at the rear in the sliding direction (receding angle) of the water drop.), a sliding angle (slope angle of photoresist film when the water drop begins to slide when the photoresist film is made to slope), the dynamic receding contact angle (contact angle at end point at the rear in the direction of movement of the water drop when the photoresist film is moved at a constant speed horizontally), etc. For example, the water repellency of the protective film is higher for larger static contact angles, advancing angles, receding angles, and dynamic receding contact angles, and conversely, for smaller sliding angles.

The dynamic contact angle and static contact angle relative to the protective film formed under the desired conditions can be measured using a commercial measurement device such as a DROP MASTER-700 (trade name, Kyowa Interface Science Co., Ltd.), AUTO SLIDING ANGLE: SA-30DM (trade name, Kyowa Interface Science Co., Ltd.), and AUTO DISPENSER: AD-31 (trade name, Kyowa Interface Science Co., Ltd.). In addition, the dynamic receding contact angle can be measured using a dynamic receding contact angle measuring instrument.

In a case of a composition for forming a protective film being used in a liquid immersion exposure process, the measurement value of the receding angle of the surface of the protective film prior to carrying out exposure and development is preferably at least 60 degrees, more preferably 60 to 150 degrees, particularly preferably 70 to 130 degrees, and most preferably 70 to 100 degrees. If the receding angle is at least the minimum value, the lens followability of the liquid for liquid immersion exposure will be improved, and the material elution suppressing effect during liquid immersion exposure will be improved while residue of droplets on the substrate of the liquid for liquid immersion exposure and the like will be reduced, even if performing scanning at high speed during exposure. In addition, if the receding angle is no more than the maximum value, the lithography characteristics will be favorable.

The measurement value of the sliding angle of the protective film prior to carrying out exposure and development is preferably no more than 30 degrees, more preferably 0.1 to 30 degrees, particularly preferably 0.1 to 25 degrees, and most preferably 0.1 to 20 degrees. If the sliding angle is no more than the maximum value, the material elution suppressing effect during the liquid immersion exposure will be improved. In addition, if the sliding angle is at least the minimum value, the lithography characteristics will be favorable.

The measurement value of the static contact angle of the protective film prior to carrying out exposure and development is preferably at least 70 degrees, more preferably 70 to 100 degrees, and particularly preferably 75 to 100 degrees. If the static contact angle is at least 70 degrees, the material elution suppressing effect during the liquid immersion exposure will be improved.

The measurement value of the dynamic receding contact angle of the protective film prior to exposure and development is preferably at least 35 degrees, more preferably 35 to 90 degrees, and particularly preferably 50 to 90 degrees. If the dynamic receding contact angle is at least 35 degrees, the lithography characteristics will be favorable.

The value of each of the aforementioned angles (static contact angle, dynamic contact angle (advancing angle, receding angle), sliding angle, dynamic receding contact angle) can be adjusted by adjusting the constitution of the composition for forming the protective film, e.g., the type and content of the unit derived from a monomer represented by the above general formula (A-1) in the alkali-soluble polymer (a), the type and content of a monomer that is allowed to copolymerize with the monomer represented by the general formula (A-1), etc.

### Photoresist Composition

The photoresist composition is not particularly limited, and any photoresist composition capable of being developed in an alkali aqueous solution, including negative and positive type photoresists, can be used.

Such a photoresist composition includes, but is not limited to, (i) positive type photoresist compositions containing a naphthoquinone diazide compound and a novolak resin, (ii) positive type photoresist compositions containing an acid generator that generates acid by exposure, a compound that decomposes by the acid to increase the solubility in the alkali aqueous solution and an alkali-soluble resin, (iii) positive type photoresist compositions containing an acid generator that generates acid by exposure and an alkali-soluble resin having a group which decomposes by the acid to increase the solubility in the alkali aqueous solution, and (iv) negative type photoresist compositions containing an acid generator that generates acid by exposure, a cross-linking agent and an alkali-soluble resin.

### Method for Forming Photoresist Pattern

A method for forming a photoresist pattern of the present invention includes steps of: providing a photoresist film on a substrate, forming a protective film on this photoresist film using the material for forming a protective film of the present invention, selectively exposing the photoresist film through the above-mentioned protective film, and removing the protective film by a developing solution and developing the photoresist film after exposure.

In particular, in a case of using a liquid immersion exposure process in exposure of the photoresist film, the method for forming a photoresist pattern of the present invention includes steps of: providing a photoresist film on a substrate; forming a protective film on this photoresist film using the material for forming the protective film of the present invention; disposing a liquid for liquid immersion exposure at least on the protective film on the above-mentioned substrate, and selectively exposing the photoresist film through the liquid for the liquid immersion exposure and the protective film; and removing the protective film by way of a developing solution, and developing the photoresist film after exposure.

A case of using a liquid immersion exposure process will be explained in detail below, since both methods are substantially the same except for whether or not the liquid for liquid immersion exposure is disposed on the protective film.

First, a protective film is provided on a substrate. More specifically, after a publicly known photoresist composition has been coated on a substrate such as a silicon wafer using a publicly known method such as spinner, prebaking (PAB treatment) is performed and the photoresist film is formed. It should be noted that the photoresist film may be formed after providing an anti-reflective film of organic type or inorganic type on the substrate (underlayer anti-reflective film).

The photoresist composition is not particularly limited, and any photoresist composition capable of being developed in an alkali aqueous solution, including negative and positive type photoresists, can be used. The aforementioned photoresist composition can be used as such a photoresist composition.

Next, a protective film is formed on the photoresist film using the material for forming a protective film of the present invention. More specifically, the protective film is formed by evenly coating the material for forming a protective film according to the present invention on the surface of the photoresist film by a similar method to that described above, and causing to harden by baking.

Next, a liquid for liquid immersion exposure is disposed at least on the protective film on the substrate. The liquid for liquid immersion exposure is not particularly limited as long as it is a liquid having a refractive index which is larger than that of the air and is smaller than that of the photoresist film to be used. Such a liquid for liquid immersion exposure includes water (pure water, deionized water) and fluorine-based inert liquids, and it is possible to use a liquid for liquid immersion exposure having a high refractive index characteristic that is anticipated to be developed in the near future. Specific examples of the fluorine-based inert liquid include liquids composed mainly of a fluorine-based compound such as C₃HCl₂F₅, C₄F₉OCH₃, C₄F₉OC₂H₅ and C₅H₃F₇. Among such liquids for the liquid immersion exposure, in terms of cost, safety, environmental problems and versatility, it is preferable to use water (pure water, deionized water); however, when an exposure light having a wavelength of 157 nm (for example, F₂ excimer laser, etc.) is used, a fluorine based solvent is preferably used from the viewpoint of less absorption of the exposure light.

Next, the photoresist film is selectively exposed through the liquid for liquid immersion exposure and the protective film. At this time, the photoresist film is blocked by the protective film from the liquid immersion medium, thereby preventing invasion of the liquid immersion medium into the resist film causing alterations such as swelling, or conversely, preventing elution of the component into the liquid immersion medium altering the optical properties such as the refractive index of the liquid immersion medium itself.

The wavelength used in exposure is not particularly limited, and is appropriately selected according to the characteristics of the resist film. For example, it can be performed using radiant rays such as ArF excimer laser, KrF excimer laser, F₂ excimer laser, extreme ultraviolet rays (EUV), vacuum ultraviolet rays (VUV), electron beam, X-ray, and soft X-ray.

When exposure in an immersed state has completed, the substrate is extracted from the liquid for liquid immersion exposure, and liquid is removed from the substrate. It should be noted that it is preferable to perform post-baking (PEB treatment) on the photoresist film as the protective film is being laminated on the photoresist film after exposure.

Next, the protective film is removed by way of an alkali-developing solution, and the photoresist film is developed after exposure. The alkali-developing solution can be used by appropriately selecting a well-known developing solution. The protective film is dissolved and removed simultaneously with a soluble portion of the photoresist film by way of this alkali developing treatment.

Finally, rinsing is performed using pure water or the like. In this rinse, the developer and protective film components and the resist composition dissolved by this developing solution on the substrate are washed away, for example, by dropping or spraying water on the substrate surface while rotating the substrate. Then, a photoresist pattern, in which the photoresist film has been patterned in a shape corresponding to a mask pattern, is obtained by drying.

The protective film obtained in this way using the material for forming a protective film of the present invention has high water repellency, and is able to form a resist pattern more effectively due to excelling in the lens followability of the liquid for liquid immersion exposure during liquid immersion exposure of scan type, and the negative influences such as the change in the refractive index from elution of a component to the liquid for liquid immersion exposure also being small.

### EXAMPLES

Although the present invention will be explained in further detail by way of Examples, the present invention is not to be limited to these Examples.

### Example 1

A material for forming a protective film was prepared using a mixed solvent composed of 80% by mass of diisoamyl ether and 20% by mass 4-methyl-2-pentanol by dissolving an alkali-soluble polymer (mass average molecular weight: 3,800, dispersivity: 1.5) composed of constitutional units represented by the following structural formula (X-1) and an acidic compound (Jemco Co., Ltd., EF-N301) represented by the following structural formula (Y) so as to be 2.2% by mass and 0.3% by mass, respectively.

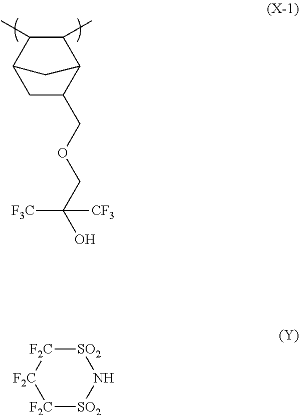

Next, an organic anti-reflective film composition “ARC-95” (trade name, Brewer Science, Inc.) was coated on a 300 mm silicon wafer using a spinner, and an organic anti-reflective film with a film thickness of 90 nm was formed by drying for 60 seconds at 205° C. on a hot plate. TARF—P6111ME (Tokyo Ohka Kogyo Co., Ltd.), which is a photoresist composition containing an acrylic resin, was coated on the anti-reflective film, and heated for 60 seconds at 110° C., thereby forming a photoresist film with a film thickness of 100 nm.

After the material for forming a protective film prepared as described above had been coated on the above-mentioned photoresist film, it was heated for 60 seconds at 90° C., thereby forming a protective film with a film thickness of 35 nm.

50 μL of water was dropped on the above-mentioned protective film surface, and the static contact angle, sliding angle, advancing angle, and receding angle were measured using a DROP MASTER-700 (Kyowa Interface Science Co., Ltd.). In addition, after 50 μL of water was dropped on the above-mentioned protective film surface, the silicon wafer was made to move horizontally at a constant speed, and the dynamic receding contact angle was measured using a dynamic receding contact angle measuring instrument (in the present Example, the static contact angle, sliding angle, advancing angle, receding angle and dynamic receding contact angle may be collectively referred to as contact angle).

Additionally, the contact angle of the resist laminated body surface in a state not provided with the above-mentioned protective film, i.e. the photoresist film surface, was measured similarly to above.

Furthermore, a substrate having the protective film was contacted with a 2.38% by mass tetramethylammonium hydroxide (TMAH) aqueous solution for 60 seconds, and the solubility in the alkali-developing solution was evaluated. The evaluation was performed by measuring the dissolution rate of the protective film due to contact with the alkali-developing solution. The contact angle and dissolution rate of the protective film are noted in Table 1.

### Example 2

A material for forming a protective film was prepared similarly to Example 1 except for the alkali-soluble polymer being changed to an alkali-soluble polymer (mass average molecular weight: 7,900, dispersivity: 1.9) composed of constitutional units represented by the following structural formula (X-2).

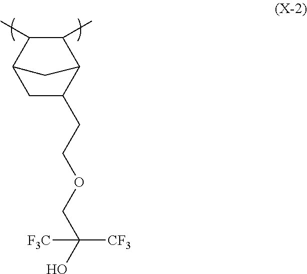

The protective film was formed on the photoresist film similarly to Example 1, and the contact angle and dissolution rate of the protective film were measured. The results thereof are noted in Table 1.

### Example 3

A material for forming a protective film was prepared similarly to Example 1 except for the alkali-soluble polymer being changed to an alkali-soluble polymer (mass average molecular weight: 20,000, dispersivity: 2.6) composed of constitutional units represented by the following structural formula (X-3).

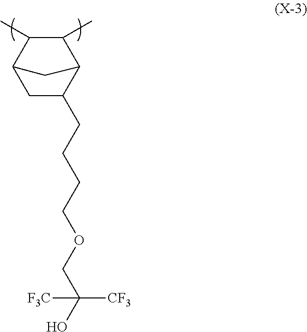

The protective film was formed on the photoresist film similarly to Example 1, and the contact angle and dissolution rate of the protective film were measured. The results thereof are noted in Table 1.

### Example 4

A material for forming a protective film was prepared similarly to Example 1 except for the alkali-soluble polymer being changed to an alkali-soluble polymer (mass average molecular weight: 10,000, dispersivity: 2.3) composed of constitutional units represented by the following structural formula (X-4).

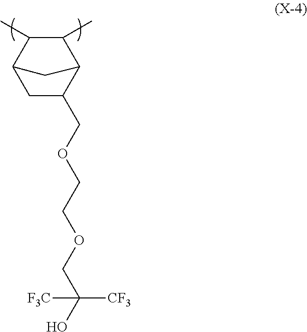

The protective film was formed on the photoresist film similarly to Example 1, and the contact angle and dissolution rate of the protective film were measured. The results thereof are noted in Table 1.

### Example 5

A material for forming a protective film was prepared similarly to Example 1 except for the alkali-soluble polymer being changed to an alkali-soluble polymer (mass average molecular weight: 5,500, dispersivity: 1.6) represented by the following structural formula (X-5). It should be noted that the numbers (86, 14) next to the parenthesis in the following structural formula (X-5) indicate the proportion (mol %) of each constitutional unit.

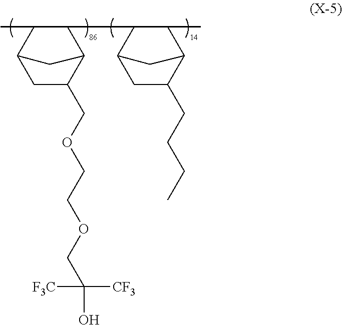

The protective film was formed on the photoresist film similarly to Example 1, and the contact angle and dissolution rate of the protective film were measured. The results thereof are noted in Table 1.

### Example 6

A material for forming a protective film was prepared similarly to Example 1 except for the alkali-soluble polymer being changed to an alkali-soluble polymer (mass average molecular weight: 5,500, dispersivity: 1.6) represented by the following structural formula (X-6). It should be noted that the numbers (81, 19) next to the parenthesis in the following structural formula (X-6) indicate the proportion (mol %) of each constitutional unit.

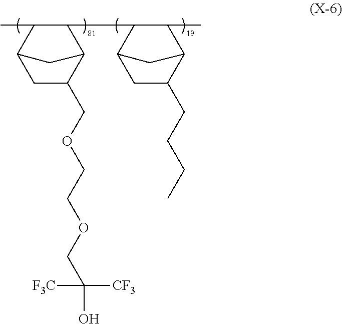

The protective film was formed on the photoresist film similarly to Example 1, and the contact angle and dissolution rate of the protective film were measured. The results thereof are noted in Table 1.

### Comparative Example 1

A material for forming a protective film was prepared similarly to Example 1 except for the alkali-soluble polymer being changed to an alkali-soluble polymer (mass average molecular weight: 4,200, dispersivity: 1.4) represented by the following structural formula (X-7). It should be noted that the numbers (60, 20, 20) next to the parenthesis in the following structural formula (X-7) indicate the proportion (mol %) of each constitutional unit.

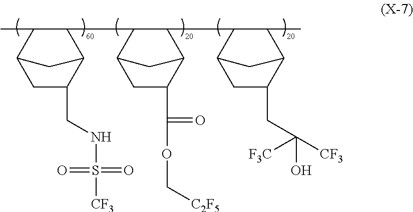

The protective film was formed on the photoresist film similarly to Example 1, and the contact angle and dissolution rate of the protective film were measured. The results thereof are noted in Table 1.

### Comparative Example 2

A material for forming a protective film was prepared similarly to Example 1 except for the alkali-soluble polymer being changed to an alkali-soluble polymer (mass average molecular weight: 4,000, dispersivity: 1.5) represented by the following structural formula (X-8). It should be noted that the numbers (20, 10, 70) next to the parenthesis in the following structural formula (X-8) indicate the proportion (mol %) of each constitutional unit.

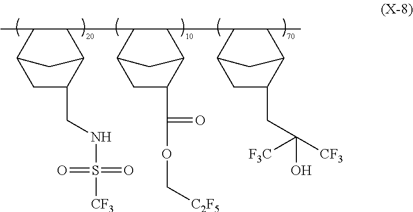

The protective film was formed on the photoresist film similarly to Example 1, and the contact angle and dissolution rate of the protective film were measured. The results thereof are noted in Table 1.

TABLE 1

| | | | | | Dynamic receding | Dissolution rate of |
|---|---|---|---|---|---|---|
| | Static contact | Sliding angle | Advancing angle | Receding angle | contact angle | the protective film |
| | angle (degrees) | (degrees) | (degrees) | (degrees) | (degrees) | (nm/second) |
| Reference | 69.0 | 21.3 | 77.2 | 54.8 | — | — |
| Example* | | | | | | |
| Example 1 | 77.3 | 15.0 | 84.6 | 70.1 | 49.5 | 1910 |
| Example 2 | 77.3 | 6.0 | 79.8 | 74.6 | 50.7 | 527 |
| Example 3 | 75.6 | 7.0 | 79.8 | 74.2 | 49.9 | 365 |
| Example 4 | 81.4 | 12.0 | 87.3 | 75.0 | 51.4 | 1939 |
| Example 5 | 83.2 | 8.5 | 86.4 | 78.1 | 58.3 | 1077 |
| Example 6 | 83.4 | 7.0 | 86.8 | 80.2 | 54.8 | 813 |
| Comparative | 78.2 | 22.7 | 89.0 | 65.6 | 43.5 | 784 |
| Example 1 | | | | | | |
| Comparative | 74.4 | 25.8 | 87.4 | 60.7 | 38.0 | 530 |
| Example 2 | | | | | | |

*The Reference Example was measured on the photoresist film.

As shown in the above Table 1, for Examples 1 to 6 using the material for forming a protective film containing an alkali-soluble polymer having a unit derived from a monomer represented by the formula (A-1) as a constitutional unit, the receding angle and dynamic receding contact angle were large while the sliding angle was small, compared to Comparative Examples 1 and 2 prepared using a material for forming a protective film containing an alkali-soluble polymer not containing a unit derived from a monomer represented by the formula (A-1) as a constitutional unit, whereby it was confirmed that the water repellency of the protective film has been improved. In addition, for Examples 1 to 6, the alkali solubilities of all of the protective films were favorable. In particular, Examples 1 and 4 have rates of dissolution of at least 1,900 nm/second, and thus clearly excel in alkali solubility.

What is claimed is:

1. A material for forming a protective film that forms a protective film that is laminated on a photoresist film, comprising an alkali-soluble polymer containing a unit derived from a monomer represented by the following general formula (A-1) as a constitutional unit, 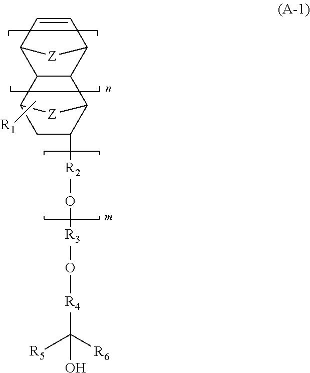
wherein R₁ is a hydrogen atom or a straight chain, branched chain or cyclic alkyl group or fluoroalkyl group having 1 to 6 carbon atoms; R₂, R₃, and R₄ are each independently an alkylene chain or fluoroalkylene chain having 1 to 6 carbon atoms; R₅ and R₆ are each independently a straight chain, branched chain or cyclic alkyl group or fluoroalkyl group having 1 to 15 carbon atoms, where a portion of the alkyl group may be bound via an ether linkage, and a portion of the hydrogen atoms of the alkyl group, or hydrogen atoms or the fluorine atoms of the fluoroalkyl group may be each substituted by a hydroxyl group; and at least one among R₅ and R₆ is a fluoroalkyl group; Z is an alkylene chain having 1 to 2 carbon atoms or an oxygen atom; m is 0 or 1; and n is an integer of 0 to 3.

2. A material for forming a protective film according to claim 1, wherein the alkali-soluble polymer has only units derived from a monomer represented by the general formula (A-1) as constitutional units.

3. A material for forming a protective film according to claim 1, further comprising an acidic compound.

4. A material for forming a protective film according to claim 1, wherein the material for forming a protective film is used in a liquid immersion exposure process.

5. A method for forming a photoresist pattern comprising the steps of:
providing a photoresist film on a substrate;
forming a protective film on the photoresist film using the material for forming the protective film according to claim 1;
selectively exposing the photoresist film through the protective film; and
removing the protective film by way of a developing solution, and developing the photoresist film after exposure.

6. A method for forming a photoresist pattern using a liquid immersion exposure process, comprising the steps of:
providing a photoresist film on a substrate;
forming a protective film on the photoresist film using the material for forming the protective film according to claim 4;
disposing a liquid for liquid immersion exposure at least on the protective film on the substrate, and selectively exposing the photoresist film through the liquid for liquid immersion exposure and the protective film; and
removing the protective film by way of a developing solution, and developing the photoresist film after exposure.
